(19) United States
(12) Patent Application Publication
(10) Pub. No.: US 2021/0159107 A1
(43) Pub. Date: May 27, 2021

(54) EDGE UNIFORMITY TUNABILITY ON BIPOLAR ELECTROSTATIC CHUCK

(71) Applicant: Applied Materials, Inc., Santa Clara, CA (US)

(72) Inventor: Hyung Je Woo, Morgan Hill, CA (US)

(73) Assignee: Applied Materials, Inc., Santa Clara, CA (US)

(21) Appl. No.: 16/690,562

(22) Filed: Nov. 21, 2019

(51) Int. Cl. H01L 21/683; H01J 37/32; C23C 16/503; C23C 16/505; C23C 16/458

(52) U.S. Cl. CPC H01L 21/6833; H01J 37/32724; H01J 37/32541; H01J 37/32082; H01J 2237/3323; C23C 16/505; C23C 16/4586; H01J 2237/3321; C23C 16/503

(57) ABSTRACT

Embodiments of the present technology may include an electrostatic chuck. The chuck may include a top surface, defining a recessed portion of the chuck. The recessed portion of the chuck may be configured to support a substrate. The chuck may further include a first electrode and a second electrode. The first electrode and the second electrode may be disposed within the chuck. The first electrode and the second electrode may be substantially coplanar. In addition, the chuck may include a third electrode. The third electrode may be disposed within the chuck. Furthermore, the third electrode may have an annular shape. The third electrode may be separated from the first electrode and the second electrode. In addition, the third electrode may be substantially parallel to the first electrode and the second electrode. Systems and methods including the electrostatic chuck are also described.

### FIELD

The present technology relates to semiconductor substrate systems and methods. More specifically, the present technology relates to methods and systems with an electrostatic chuck having multiple electrodes.

### BACKGROUND

In the manufacture of integrated circuits and other electronic devices, plasma processes are often used for deposition or etching of various material layers. For example, plasma-enhanced chemical vapor deposition (PECVD) process is a chemical process wherein electro-magnetic energy is applied to at least one precursor gas or precursor vapor to transform the precursor into a reactive plasma. Plasma may be generated inside the processing chamber, e.g., in-situ, or in a remote plasma generator that is remotely positioned from the processing chamber. This process is widely used to deposit materials on substrates to produce high-quality and high-performance semiconductor devices.

In the current semiconductor manufacturing industry, transistor structures have become increasingly complicated and challenging as feature size continues to decrease. To meet processing demands, advanced processing control techniques are useful to control cost and maximize substrate and die yield. Normally, the dies at the edge of the substrate suffer yield issues such as contact via misalignment, and poor selectivity to a hard mask. On the substrate processing level, there is a need for advancements in process uniformity control to allow fine, localized process tuning as well as global processing tuning across the whole substrate.

Therefore, there is a need for methods and apparatuses to allow fine, localized process tuning at the edge of the substrate. These and other needs are addressed by the present technology.

### BRIEF SUMMARY

Embodiments of the present technology may allow for advantages in handling and processing substrates by using at least two bipolar electrodes and one annular electrode in the substrate support. The electrode configuration may allow for better tunability of ion flux near the edge of the wafer, which may result in higher uniformity of deposited films. In addition, the combination of bipolar electrodes and an annular electrode may reduce voltage needed to electrostatically chuck a wafer. The reduced voltage may result in less arcing and fewer wafer defects. Furthermore, embodiments of the present technology may reduce the effect of electrostatic charge in the wafer on the plasma. As a result, the plasma may be ignited after a wafer has been chucked rather than at the same time, and short-term plasma instabilities may be reduced during the ignition of the plasma.

Embodiments of the present technology may include an electrostatic chuck. The chuck may include a top surface. The top surface may define a recessed portion of the chuck. The recessed portion of the chuck may be configured to support a substrate. The recessed portion of the chuck may be characterized by a first diameter. The chuck may further include a first electrode and a second electrode. The first electrode and the second electrode may be disposed within the chuck. The first electrode and the second electrode may be substantially coplanar. The first electrode may be separated from the second electrode. In addition, the chuck may include a third electrode. The third electrode may be disposed within the chuck. Furthermore, the third electrode may have an annular shape. The third electrode may be characterized by an inner diameter. The inner diameter may be greater than the first diameter. The third electrode may be separated from the first electrode and the second electrode. In addition, the third electrode may be substantially parallel to the first electrode and the second electrode.

Embodiments of the present technology may include a plasma processing system. The plasma processing system may include an electrostatic chuck. The chuck may include any chuck disclosed herein. The system may further include a first power source in electrical communication with the first electrode and the second electrode. The first electrode and the second electrode may be connected to the first power source such that the first electrode and the second electrode have opposite voltages when the first power source delivers voltage to the first electrode. The system may further include a second power source in electrical communication with the third electrode.

Embodiments of the present technology may include a method of processing a substrate. The method may include disposing the substrate on an electrostatic chuck. The electrostatic chuck may include a first electrode, a second electrode, and a third electrode. The first electrode and the second electrode may be substantially coplanar. The third electrode may have an annular shape. The method may also include applying a first voltage to the first electrode. The method may further include applying a second voltage to the second electrode. The second voltage may be the opposite voltage of the first voltage. In addition, the method may include applying a third voltage to the third electrode.

These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2A shows a top view of a substrate support assembly according to some embodiments of the present technology.

FIG. 2B shows the electrical configuration of electrodes according to some embodiments of the present technology.

FIG. 3 shows a partial perspective view of a substrate support assembly according to some embodiments of the present technology.

FIG. 4 shows exemplary operations in processing a substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As characteristic dimensions of semiconductor devices decrease, processing becomes more complicated and additional challenges result. Layers deposited near the edge of a substrate may not be as uniform as those near the center of the substrate. The non-uniformities near the edge of the wafer may result in non-functional or poor performing devices, reducing yield and/or reliability. Wafers are often not completely flat and are electrostatically chucked to reduce any wafer bow. However, electrostatically chucking the wafer may result in arcing at the backside of the wafer. Previously when semiconductor devices were larger, arcing at the backside of the wafer may not have been a high concern, but processing to produce smaller devices sometimes includes materials deposited on the backside of the wafer. Such arcing may create defects on the backside of the wafer, which may in turn lead to defects on the frontside of the wafer. In addition, conventionally electrostatically chucking the wafer may build up charge on the wafer and may affect the ignition and stability of a plasma. Embodiments of the present technology may overcome these challenges, as described below.

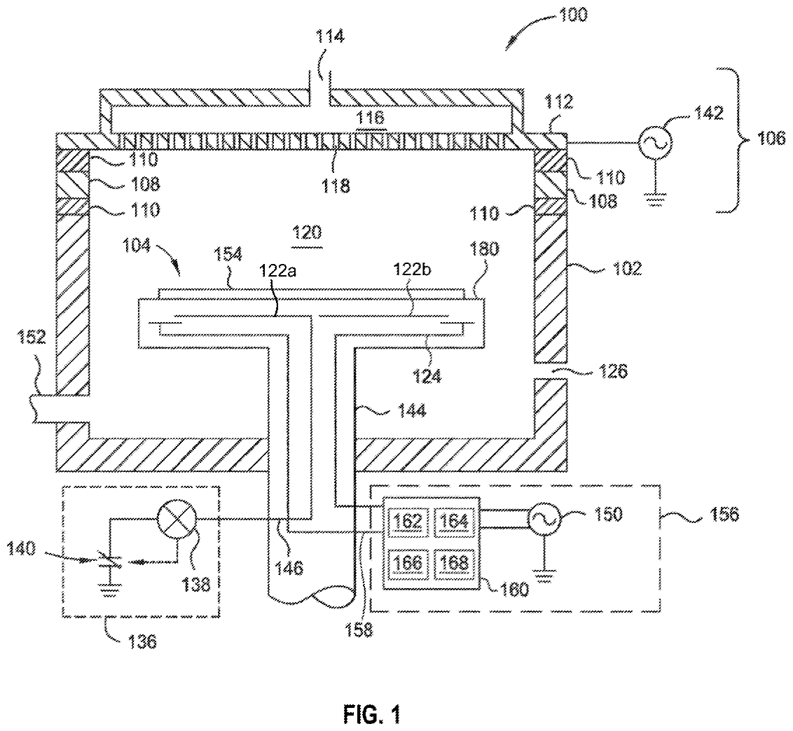

FIG. 1 is a cross sectional view of a processing chamber 100, according to one or more embodiments. In one or more examples, the processing chamber 100 is a deposition chamber, such as a plasma-enhanced chemical vapor deposition (PECVD) chamber, suitable for depositing one or more materials on a substrate, such as a substrate 154. In other examples, the processing chamber 100 is an etch chamber suitable for etching a substrate, such as the substrate 154. Examples of processing chambers that may be adapted to benefit from exemplary aspects of the disclosure are Producer® Etch Processing Chamber, and Precision™ Processing Chamber, commercially available from Applied Materials, Inc., located in Santa Clara, Calif. It is contemplated that other processing chambers, including those from other manufacturers, may be adapted to benefit from aspects of the disclosure.

The processing chamber 100 may be used for various plasma processes. In one aspect, the processing chamber 100 may be used to perform dry etching with one or more etching agents. For example, the processing chamber may be used for ignition of plasma from a precursor, such as one or more fluorocarbons (e.g., CF₄ or C₂F₆), O₂, NF₃, or any combination thereof. In another implementation the processing chamber 100 may be used for PECVD with one or more chemical agents.

The processing chamber 100 may include a chamber body 102, a lid assembly 106, and a substrate support assembly 104. The lid assembly 106 may be positioned at an upper end of the chamber body 102. The lid assembly 106 and the substrate support assembly 104 may be used with any processing chamber for plasma or thermal processing. Other chambers available from any manufacturer may also be used with the components described above. The substrate support assembly 104 may be disposed inside the chamber body 102, and the lid assembly 106 may be coupled to the chamber body 102 and enclosing the substrate support assembly 104 in a processing volume 120. The chamber body 102 includes a slit valve opening 126 formed in a sidewall thereof. The slit valve opening 126 may be selectively opened and closed to allow access to the interior volume 120 by a substrate handling robot (not shown) for substrate transfer.

An electrode 108 may be disposed adjacent to the chamber body 102 and may separate the chamber body 102 from other components of the lid assembly 106. The electrode 108 may be part of the lid assembly 106, or may be a separate side wall electrode. The electrode 108 may be an annular or ring-like member, such as a ring electrode. The electrode 108 may be a continuous loop around a circumference of the processing chamber 100 surrounding the processing volume 120, or may be discontinuous at selected locations, if desired. The electrode 108 may also be a perforated electrode, such as a perforated ring or a mesh electrode. The electrode 108 may also be a plate electrode, for example, a secondary gas distributor.

An isolator 110 contacts the electrode 108 and separates the electrode 108 electrically and thermally from a gas distributor 112 and from the chamber body 102. The isolator 110 may be made from or contain one or more dielectric materials. Exemplary dielectric materials can be or include one or more ceramics, metal oxides, metal nitrides, metal oxynitrides, silicon oxides, silicates, or any combination thereof. For example, the isolator 110 may be formed from or contain aluminum oxide, aluminum nitride, aluminum oxynitride, or any combination thereof. The gas distributor 112 features openings 118 for admitting process gas into the processing volume 120. The process gases may be supplied to the processing chamber 100 via one or more conduits 114, and the process gases may enter a gas mixing region 116 prior to flowing through one or more openings 118. The gas distributor 112 may be coupled to an electric power source 142, such as an RF generator. DC power, pulsed DC power, and pulsed RF power may also be used.

The substrate support assembly 104 may include a substrate support 180 that holds or supports one or more substrates 154 for processing. The substrate support 180 may be coupled to a lift mechanism through a shaft 144, which extends through a bottom surface of the chamber body 102. The lift mechanism may be flexibly sealed to the chamber body 102 by a bellow that prevents vacuum leakage from around the shaft 144. The lift mechanism may allow the substrate support assembly 104 to be moved vertically within the chamber body 102 between a lower transfer position and a number of raised process positions.

The substrate support 180 may be formed from or contain a metallic or ceramic material. Exemplary metallic or ceramic materials can be or include one or more metals, metal oxides, metal nitrides, metal oxynitrides, or any combination thereof. For example, the substrate support 180 may be formed from or contain aluminum, aluminum oxide, aluminum nitride, aluminum oxynitride, or any combination thereof. Bipolar electrodes 122a and 122b may be coupled to the substrate support assembly 104. Bipolar electrodes 122a and 122b may be embedded within the substrate support 180 and/or coupled to a surface of the substrate support 180. Bipolar electrodes 122a and 122b may each be a plate, a perforated plate, a mesh, a wire screen, or any other distributed arrangement.

Bipolar electrodes 122a and 122b may each be a tuning electrode, and may be coupled to a tuning circuit 136 by a conduit 146, for example a cable having a selected resistance, such as 50Ω, disposed in a shaft 144 of the substrate support assembly 104. The tuning circuit 136 may include an electronic sensor 138 and an electronic tuner or controller 140, which may be a variable capacitor. The electronic sensor 138 may be a voltage or current sensor, and may be coupled to the electronic tuner or controller 140 to provide further control over plasma conditions in the processing volume 120. In one or more aspects, the electronic tuner or controller 140 can be used to modulate impedance on bipolar electrodes 122a and 122b.

Both bipolar electrode 122a and 122b may be in electrical communication with electronic sensor 138. In other embodiments, bipolar electrode 122a may be in electrical communication with electronic sensor 138, and bipolar electrode 122b may independently be in electrical communication with a second electronic sensor and second electronic tuner or controller, both of which may be identical to electronic sensor 138 and electronic tuner or controller 140. Bipolar electrodes 122a and 122b may be in electrical communication with a power source (not shown). Bipolar electrodes 122a and 122b may be bias electrodes and/or electrostatic chucking electrodes. Bipolar electrodes 122a and 122b may also be heaters for substrate support 180.

An annular electrode 124 may be coupled to the substrate support assembly 104. The annular electrode 124 may be embedded within the substrate support 180. Bipolar electrodes 122a and 122b may be disposed above an upper portion of the annular electrode 124. In some examples, the annular electrode 124 is a bias electrode and/or an electrostatic chucking electrode. The annular electrode 124 may be coupled to a tuning circuit 156 by one or more cables or conduits 158 which are disposed in the shaft 144 of the substrate support assembly 104. The tuning circuit 156 may include to an electric power source 150 and a process controller 160 electrically coupled to the annular electrode 124.

The electric power source 150 may illustratively be a source of electricity of up to about 1,000 W (but not limited to about 1,000 W) of RF energy at a frequency of, for example, approximately 13.56 MHz, although other frequencies and powers may be applied or otherwise provided as desired for particular applications. The electric power source 150 may be capable of producing either or both of continuous or pulsed power. In one or more examples, the bias source may be a direct current (DC) or pulsed DC source. In other examples, the bias source may be capable of providing multiple frequencies, such as 2 MHz and 13.56 MHz.

The process controller 160 may include a DC power supply 162, an RF generator 164, one or more electronic sensors 166, and one or more electronic tuners or controllers 168. The DC power supply 162 may supply voltage to the annular electrode 124 and the RF generator 164 may apply the RF frequency during the plasma process. The DC power supply 162 may supply and control a voltage from 0 V to about 1,000 V. In one or more aspects, the electronic tuner or controller 168 can be used to modulate impedance on the annular electrode 124. For example, the electronic tuner or controller 168 can be used to control impedance with a variable capacitor such that about 5% to about 95% of the impedance is controlled to the annular electrode 124. In some aspects, the electronic sensor 166 may be a voltage or current sensor, and may be coupled to the electronic tuner or controller 168 to provide further control over plasma conditions in the processing volume 120.

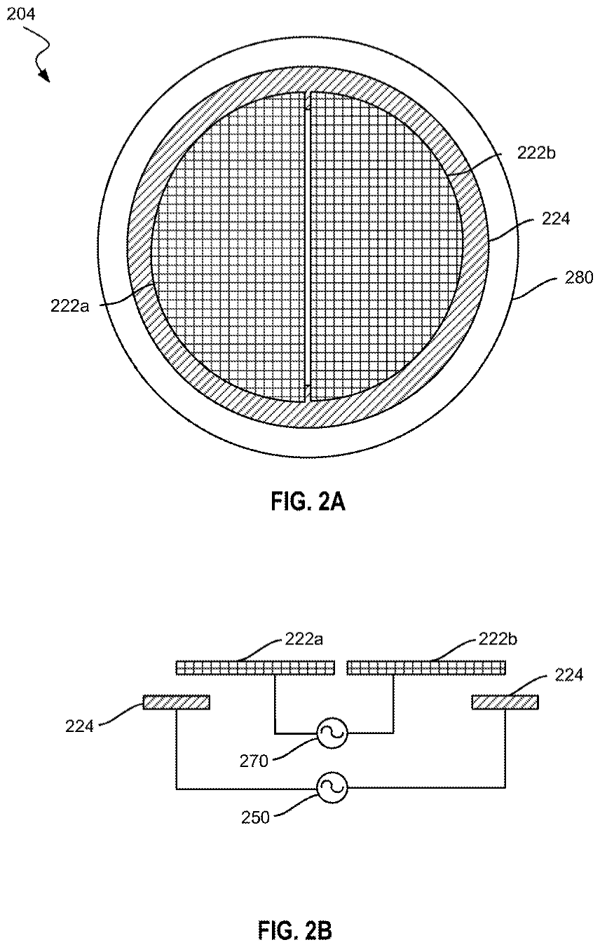

FIG. 2A illustrates a top view of the substrate support assembly 204, according to one or more embodiments. Substrate support assembly 204 may be substrate support assembly 104. Substrate support assembly 204 may include bipolar electrodes 222a and 222b, which may be bipolar electrodes 122a and 122b. Bipolar electrodes 222a and 222b may be separated by a gap, which may be filled by an insulator. The insulator may be the body of the substrate support assembly 204. The width of the gap may be reduced or minimized. The width may be from 0.01 to 0.05 in, 0.05 to 0.1 in, 0.1 to 0.25 in, 0.25 to 0.5 in, or from 0.5 in to 1.0 in. Annular electrode 224 may be disposed under bipolar electrodes 222a and 222b. Annular electrode 224 may be annular electrode 124.

Bipolar electrodes 222a and 222b and the annular electrode 224 may independently be embedded or partially embedded in the substrate support 280. Substrate support 280 may be substrate support 180. Bipolar electrodes 222a and 222b may be a plate, a perforated plate, a mesh, a wire screen, or any other distributed arrangement. Bipolar electrodes 222a and 222b may be formed from or contains one or more electrically conductive metals or materials, such as, aluminum, copper, alloys thereof, or any mixture thereof. Annular electrode 224 may be a circular ring. However, other shapes are contemplated. Annular electrode 224 may be continuous or have spaces throughout. In some implementations, bipolar electrode 222a and the annular electrode 124 are cathodes.

In one or more examples, the combined surface area of bipolar electrodes 222a and 222b have a greater surface area than annular electrode 224. In some examples, the annular electrode 224 has a greater outer diameter than the diameter of bipolar electrodes 222a and 222b. Annular electrode 224 may be formed from or contains one or more electrically conductive metals or materials, such as, aluminum, copper, alloys thereof, or any mixture thereof. Annular electrode 224 may surround bipolar electrodes 222a and 222b. In some embodiments, annular electrode 224 at least partially overlaps with bipolar electrodes 222a and 222b.

Bipolar electrodes 222a and 222b and annular electrode 224 may be coupled to separate power sources as shown in FIG. 2B. Annular electrode 225 may be coupled to power source 250. Bipolar electrodes 222a and 222b may be coupled to power source 270. Bipolar electrodes 222a and 222b may be configured to receive equal and opposite voltages of power source 270. Power source 250 and power source 270 may independently be a DC power supply or an RF power supply, with any powers, voltages, or frequencies described herein, including any powers, voltages, or frequencies described in FIG. 1. For clarity of the illustration, FIG. 2B does not show controllers, filters, tuners, or sensors, which may be included with power sources 250 and 270. However, any suitable controllers, filters, tuners, or sensors may be included.

The plurality of bipolar electrodes 222a and 222b and the annular electrode 224 may be independently powered and controlled. The power distribution to the bipolar electrodes 222a and 222b may be a separate path than to the annular electrode 124. As such, the travel path of the electrical current may be spilt into separate sections facilitating a wider distribution and may then improve process uniformity. Additionally, the vertical separation between annular electrode 224 and bipolar electrodes 222a and 222b may extend the coupling power and may increase the process uniformity.

In some implementations, the bipolar electrodes 222a and 222b may function as a chucking electrode while also functioning as RF or DC electrodes. Annular electrode 224 may be an RF or DC electrode that together with bipolar electrodes 222a and 222b may tune the plasma. Bipolar electrodes 222a and 222b and annular electrode 224 may produce power at the same frequency or at different frequencies.

In one or more embodiments, the RF power from one or both of power source 250 and power source 270 may be varied in order to tune the plasma. For example, a sensor (not shown) may be used to monitor the RF energy from any one or any combination of bipolar electrodes 222a and 222b and annular electrode 224. Data from the sensor device may be communicated and utilized to vary power applied to power source 250 and/or power source 270.

In another embodiment, a first impedance and/or voltage may be applied or otherwise provided to bipolar electrodes 222a and 222b, and independently, a second impedance and/or voltage may be applied or otherwise provided to the annular electrode 124. Parameters of the first impedance and/or voltage and parameters of the second impedance and/or voltage can independently be monitored, controlled, and adjusted based on the monitoring parameters. Each of the first and/or second impedances can independently be increased and/or decreased, such as being modulated, in order to improve uniformity across the upper surface of the substrate. Also, each of the first and/or second voltages can independently be increased, decreased, modulated, or otherwise adjusted in order to improve the uniformity on the substrate surface.

In one or more examples, each of the first and/or second impedances and/or the first and/or second voltages can independently be modulated to decrease an in plane distortion (IPD) of the uniformity of the substrate surface by 40% or greater, relative to the IPD of the substrate surface prior to adjusting or modulating any of the impedances or voltages, without changing the profile. For example, each of the first and/or second impedances and/or the first and/or second voltages can independently be modulated to decrease the IPD of the substrate surface uniformity by about 50%, about 60%, about 70%, or greater, without changing the profile. In some examples, the IPD of the plasma uniformity can be reduced by about 40% to about 70% relative to the IPD of the substrate surface uniformity prior to adjusting or modulating any of the impedances or voltages, without changing the profile.

In one implementation, bipolar electrodes 222a and 222b are powered at the same time as annular electrode 224. In one implementation, bipolar electrodes 222a and 222b are on while the annular electrode 224 is off In one implementation, bipolar electrodes 222a and 222b are off while annular electrode 224 is on. Modulating between powering bipolar electrodes 222a and 222b and annular electrode 224 may facilitate control of plasma characteristics at the substrate edge. Additionally, individually tuning the power source to each of and annular electrode 224 and bipolar electrodes 222a and 222b may result in increased or decreased plasma density. Changing the voltage/current distribution across bipolar electrodes 222a and 222b and annular electrode 224 may facilitate the spatial distribution of the plasma across the substrate.

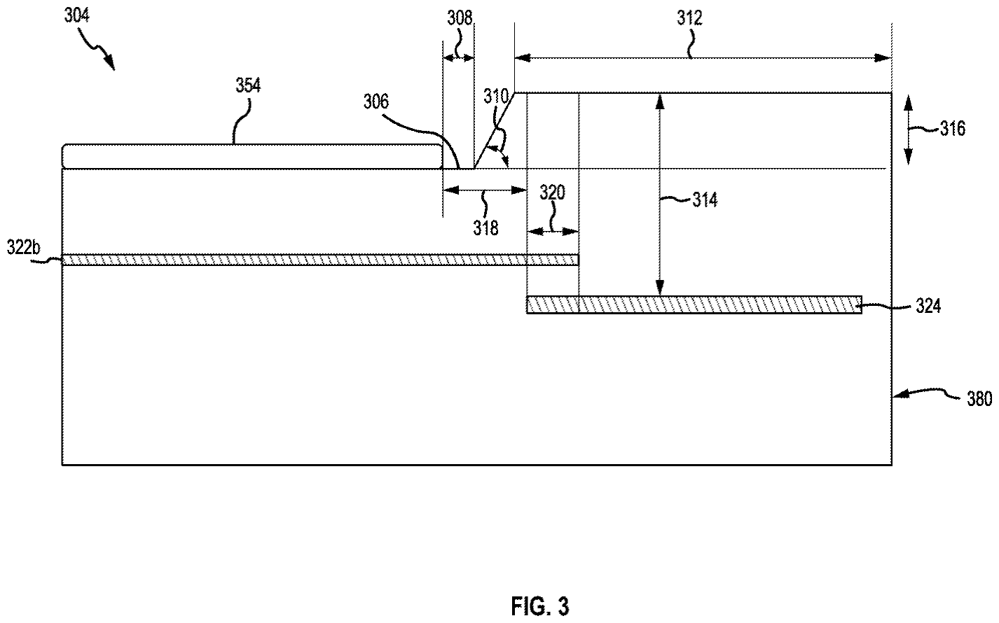

FIG. 3 depicts a partial perspective view of a substrate support assembly 304 that includes the substrate support 380, according to one or more embodiments. In this implementation, the substrate 354 is positioned or otherwise disposed above bipolar electrode 322b, which is above annular electrode 324. Bipolar electrode 322b and annular electrode 324 are shown as horizontally overlapping with each other. Substrate 354 is disposed within recessed portion 306 of substrate support 380. Annular electrode 324 is disposed within substrate support 380, such that annular electrode 324 circumferentially surrounds substrate 354 and recessed portion 306. Substrate support assembly 304, substrate support 380, bipolar electrode 322b, and annular electrode 324 may be any similar component described herein, including those described with FIG. 1, FIG. 2A, and FIG. 2B. Although only one bipolar electrode is shown, substrate support assembly 304 may be symmetric about a diameter of substrate support assembly 304 so that a second bipolar electrode is on the other side of substrate support assembly 304.

Various dimensions are illustrated in FIG. 3. Distance 308 between the edge of substrate 354 and edge of recessed portion 306 may be from 0.01 to 0.25 in. Angle 310 from the edge of recessed portion 306 may be from 0 to 90 degrees. A more vertical angle may increase undesired scattering of ions. Width 312 for the flat portion at the edge of substrate support 380 may be from 0.25 to 1.23 in. Distance 314 from top of substrate support 380 to the top of annular electrode 324 may be from 0.01 to 0.3 in. Height 316 from the top of substrate support 380 to recessed portion 306 may be from 0 to 0.25 in. Lateral distance 318 from edge of substrate 354 to annular electrode 324 may be from 0.005 to 0.2 in. Overlap width 320 of bipolar electrode 322b and annular electrode 324 may be from −0.25 to 0.25 in, including 0 in. A negative overlap width 320 means that bipolar electrode 322b and annular electrode 324 do not overlap and instead are separated by a gap. The dimensions in FIG. 3 may be for substrate 354 having a diameter of 300 mm. For substrates having larger or smaller diameters, the dimensions may scale linearly with the substrate diameter or the same range of dimensions may apply.

Benefits of the present technology may include increased control of plasma adjacent edges of a substrate. The voltages or impedances to three electrodes can be varied to control the plasma. Increasing the plasma control results in increased plasma uniformity. Controlling the power of the annular electrode may allow for more uniform deposition or etching at the edge of a substrate. The annular electrode may affect ion flux at the edge of the wafer. Changing the impedance or capacitance of the annular electrode may also change the impedance of the plasma. The uniformity at the edge of the wafer may be improved at certain voltages. The average range of thicknesses of a deposited film at positions in the range from 135 to 148 mm (with 0 mm being the center of the wafer) as a percentage of the thickness at the center of the wafer may be from 1% to 2%, 2% to 3%, or 3% to 4%.

In addition, embodiments of the present technology may reduce chucking voltage, which may reduce arcing and may also reduce backside damage to the wafer. Using three electrodes (two bipolar electrodes and one annular electrode) may reduce the chucking voltage. The chucking voltage while using two bipolar electrodes and one annular electrode was found to decrease the lowest chucking voltage needed before the onset of plasma impedance instabilities. For example, with a monopolar electrode and an annular electrode, plasma impedance instabilities were seen at voltages of 600 V and lower. By contrast, with bipolar electrodes and an annular electrode, plasma impedance instabilities were seen at voltages of 200 V and lower. The lower chucking voltages may be achieved because the annular electrode may act as a confinement ring to reduce leakage current from the bipolar electrodes.

To provide some margin over the voltages where plasma impedances are observed, the minimum chucking voltage for bipolar electrodes may be set at ±300 V, as an example, while the minimum chucking voltage for a monopolar electrode may be set at −700 V, as an example. The chucking voltage may decrease by more than 50%, which is surprisingly by being more than what would be expected from the addition of one other electrode for electrostatic chucking. In some embodiments, the chucking voltage may decrease by 30% to 40%, 40% to 50%, 50% to 60%, 60% to 70%, 70% to 80%, or 80% to 90% when using bipolar electrodes with an annular electrode compared to either a monopolar electrode or a monopolar electrode with an annular electrode. Decreasing the chucking voltage may reduce arcing at the backside of the wafer, which in turn may reduce wafer defects. In some instances, the backside of a wafer may have deposited films, which may be damaged by arcing at the surface of a substrate support. Decreasing the chucking voltage may also reduce operational costs and increase lifetime of equipment, including any part of the substrate support assembly described herein. In some instances, the chucking voltage of bipolar electrodes may be the same or near the chucking voltage of a monopolar electrode, but the area of the bipolar electrodes may be reduced. For example, the total area of the bipolar electrodes may be from 50% to 60%, 60% to 70%, 70% to 80%, 80% to 90%, or 90% to 95% the area of the substrate.

Another benefit of some embodiments of the present technology is the ability to turn the plasma on after a substrate is electrostatically chucked to the substrate support. In systems with a monopolar electrode, electrostatically chucking the wafer charges the wafer, which may affect the plasma, which has a positive charge. Turning on the plasma at the same time as chucking the wafer may result in transient plasma behaviors, which may negatively impact processing of a substrate. In embodiments of the present technology, bipolar electrodes even out the charging of the wafer so that the effect of the electrostatic chucking of the wafer on the plasma is reduced.

Embodiments of the present technology may include an electrostatic chuck. The chuck may be substrate support assembly 104, substrate support assembly 204, or substrate support assembly 304. The chuck may include a top surface. The top surface may define a recessed portion of the chuck (e.g., recessed portion 306). The recessed portion of the chuck may be configured to support a substrate. The substrate may be a semiconductor wafer, including a silicon wafer or a silicon-on-insulator wafer. The substrate may by substrate 154 or substrate 354. The recessed portion of the chuck may be substantially flat. The recessed portion of the chuck may be circular in shape and may be characterized by a first diameter. The first diameter may be greater than the diameter of the substrate, and the substrate may sit within the recessed portion.

The chuck may also include an insulator. The insulator may be the body of the chuck. The insulator may include any metallic, ceramic material, or insulating material described herein. As an example, the insulator may include alumina. In some embodiments, the insulator may be air or vacuum within the body of the chuck.

The chuck may further include a first electrode and a second electrode. The first electrode and the second electrode may be any bipolar electrode described herein, including for example, bipolar electrodes 122a, 122b, 222a, and 222b. The first electrode and the second electrode may be substantially coplanar. For example, the first electrode and the second electrode may be at the same vertical height, the height along a line orthogonal to a substrate supported by the chuck. The first electrode may be separated from the second electrode. The first electrode and second electrode may be separated by the insulator. For example, in FIG. 2A, bipolar electrodes 222a and 222b are separated by a uniform gap. The uniform gap may be the insulator, even though the insulator is not shown in FIG. 2A. The first electrode and the second electrode may include a mesh or any material described herein. A mesh may be preferred over a plate because less charge may accumulate in the mesh, which may reduce arcing, handling, and other issues when the electrodes are discharged when a substrate is de-chucked.

The first electrode and the second electrode may have substantially the same surface area. The first electrode may be substantially semicircular. The second electrode may be substantially semicircular. For example, if the first electrode and the second electrode are brought together to contact each other along a straight edge, the first electrode and the second electrode may form a circle or substantially a circle.

The first electrode and the second electrode may be characterized by a second diameter. For example, the second diameter may be the diameter of the smallest circle that circumscribes the first electrode and the second electrode as disposed in the chuck. The second diameter may be greater than the first diameter of the recessed portion.

The first electrode may be configured such that when a substrate is disposed in the recessed portion and a first voltage is applied to the first electrode, a first electrostatic force holds the substrate to the chuck. The second electrode may be configured such that when a substrate is disposed in the recessed portion and a second voltage is applied to the second electrode, a second electrostatic force holds the substrate to the chuck. The second voltage may have the opposite polarity as the first voltage. The first voltage may have the same magnitude as the second voltage but may be negative instead of positive voltage.

In some embodiments, the chuck may include one or more electrodes additional to the first electrode and the second electrode. Each of the first electrode, the second electrode, and the one or more electrodes may have substantially the same area. The same area may allow equal amounts of positive and negative charges on the substrate so that the charges have equal force on the substrate to immobilize the substrate. The outer edges of the first electrode, the second electrode, and the one or more electrodes may trace the circumference of a circle. For example, each electrode may be a sector of a circle. In total, the chuck may include 2, 4, 6, or 8 sectors of a circle as electrodes.

In addition, the chuck may include a third electrode. The third electrode may have an annular shape. The third electrode may include any annular electrode described herein, including for example, annular electrode 124, annular electrode 224, or annular electrode 324. The third electrode may be characterized by an inner diameter, where the inner diameter characterizes the circular hole within the annulus of the third electrode. The inner diameter may be greater than the first diameter of the recessed portion. The inner diameter may be less than the second diameter of the first electrode and the second electrode. The third electrode may be separated from the first electrode and the second electrode. The insulator may separate the third electrode from the first electrode and the second electrode.

The third electrode may be characterized by an outer diameter. The outer diameter may be the diameter of the smallest circle that circumscribes the third electrode. The outer diameter may be greater than the second diameter of the first electrode and the second electrode.

The third electrode may be substantially parallel to the first electrode and the second electrode. The third electrode may be disposed farther from the top surface than the first electrode is from the top surface. The third electrode may be lower than the substrate, the first electrode, and the second electrode. The third electrode being lower than the substrate may reduce arcing to the substrate. In particular, if the third electrode is above the substrate in a non-recessed portion of the substrate support, some arcing may form at the edge of the substrate. The third electrode may include a mesh or any material described herein.

Embodiments of the present technology may include a plasma processing system. The plasma processing system may include an electrostatic chuck, which may be any chuck described herein. The system may include a first power source in electrical communication with the first electrode and the second electrode. The first power source may be power source 270. The first electrode and the second electrode may be connected to the first power source such that the first electrode and the second electrode have opposite voltages when the first power source delivers voltage to the first electrode. The first power source may be a DC power source or an RF power source. The system may further include a second power source in electrical communication with the third electrode. The second power source may be an RF power source or a DC power source.

In some embodiments, the plasma processing system may include a computer system. The computer system may include a non-transitory computer readable medium storing a plurality of instructions. The plurality of instructions may include any method described herein, include method 400 described below. One or more processors may execute the instructions by sending commands to components of the plasma processing system. Components of the plasma processing system may include substrate handling robotics to move the substrate into a processing, onto a chuck, off the chuck, and out of the processing region.

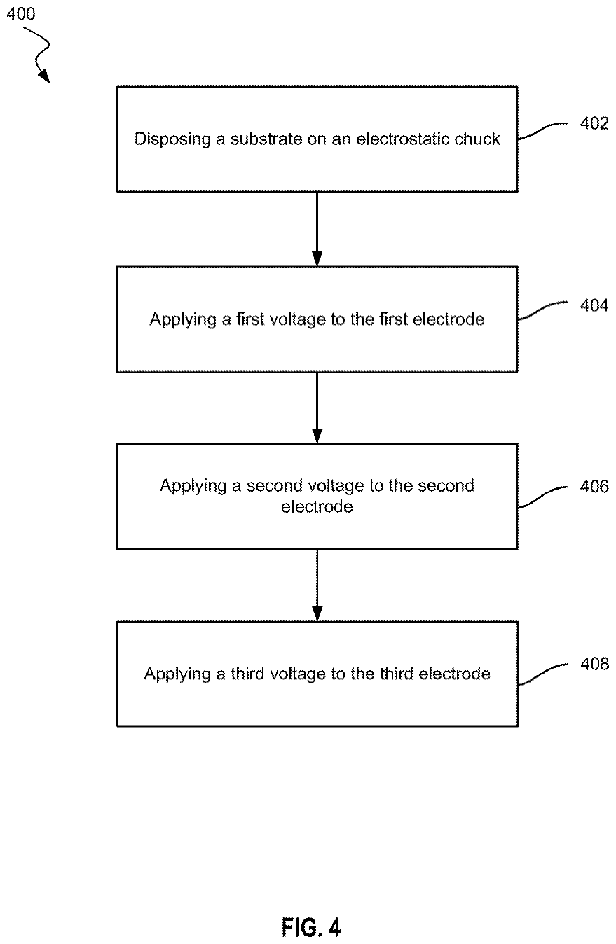

FIG. 4 shows exemplary operations of a method 400 in processing a substrate according to some embodiments of the present technology. Method 400 may include using any chuck or system described herein.

At block 402, method 400 may include disposing a substrate on an electrostatic chuck. The electrostatic chuck may be any electrostatic chuck described herein, including substrate support assembly 104, substrate support assembly 204, or substrate support assembly 304. The electrostatic chuck may include a first electrode, a second electrode, and a third electrode. The first electrode and the second electrode may be substantially coplanar. The third electrode may have an annular shape. The electrodes may be any electrodes described herein.

At block 404, method 400 may include applying a first voltage to the first electrode. The first voltage may be a DC voltage or an RF voltage. If the first voltage is a DC voltage, the first voltage may have a voltage with a magnitude from 50 V to 100 V, 100 V to 200 V, 200 V to 300 V, or 300 V to 400 V. If the first voltage is an RF voltage, then first voltage may have a maximum voltage 50 V to 100 V, 100 V to 200 V, 200 V to 300 V, or 300 V to 400 V.

At block 406, method 400 may include applying a second voltage to the second electrode. The second voltage may be the opposite voltage of the first voltage. For example, if the first voltage is positive, then the second voltage is negative with the same magnitude. In some embodiments, the second voltage may have a different magnitude than the first voltage. If the second voltage is RF, then the second voltage may be the opposite voltage of the first voltage at an instant, and the average second voltage may be the same as the average first voltage.

At block 408, method 400 may include applying a third voltage to the third electrode. The third voltage may be an RF voltage. The ratio of the magnitude of the maximum third voltage applied to the magnitude of the maximum first voltage applied may be from 0.1 to 0.5, 0.5 to 1.0, 1.0 to 1.5, 1.5 to 2.0, 2.0 to 3.0, or 3.0 or more.

In addition, method 400 may include heating the electrostatic chuck to a temperature from 500° C. to 600° C., 600° C. to 700° C., or greater than 700° C. Method 400 may further include forming a plasma in a processing region. The plasma may be formed after applying power to the bipolar electrodes. The substrate may be disposed in the processing region. Method 400 may include extinguishing the plasma and removing the substrate from the processing region and the plasma processing system.

A plasma may be tuned with the bipolar electrodes and the annular electrode. In one or more embodiments, a method for tuning a plasma in a chamber may include applying a first radio frequency power to the bipolar electrodes and applying a second radio frequency power to the annular electrode. The method may also include monitoring parameters of the first and second radio frequency powers and adjusting one of or both of the first and second radio frequency powers based on the monitored parameters.

In other embodiments, a method for tuning a plasma in a chamber may include applying a first impedance, a first voltage, or a combination of the first impedance and voltage to the bipolar electrodes and applying a second impedance, a second voltage, or a combination of the second impedance and voltage to the annular electrode. The method may also include monitoring one or more parameters of the first impedance, the second impedance, the first voltage, the second voltage, or any combination thereof and adjusting one or more of the first impedance, the second impedance, the first voltage, the second voltage, or any combination thereof based on the monitored parameters.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an electrode” includes a plurality of such electrodes, and reference to “the power source” includes reference to one or more power sources and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. An electrostatic chuck, the chuck comprising:
a top surface, wherein:
the top surface defines a recessed portion of the chuck,
the recessed portion of the chuck is configured to support a substrate, and
the recessed portion of the chuck is characterized by a first diameter;
a first electrode and a second electrode, wherein:
the first electrode and the second electrode are disposed within the chuck,
the first electrode and the second electrode are substantially coplanar, and
the first electrode is separated from the second electrode; and
a third electrode, wherein:
the third electrode is disposed within the chuck,
the third electrode has an annular shape,
the third electrode is characterized by an inner diameter,
the inner diameter is greater than the first diameter,
the third electrode is separated from the first electrode and the second electrode, and
the third electrode is substantially parallel to the first electrode and the second electrode.

2. The chuck of claim 1, wherein the first electrode and the second electrode have substantially the same surface area.

3. The chuck of claim 1, wherein:
the first electrode comprises a mesh, and
the second electrode comprises a mesh.

4. The chuck of claim 1, wherein:
the third electrode comprises a mesh.

5. The chuck of claim 1, wherein the third electrode is disposed farther from the top surface than the first electrode is from the top surface.

6. The chuck of claim 1, wherein:
the first electrode and the second electrode are characterized by a second diameter, and
the second diameter is greater than the inner diameter.

7. The chuck of claim 6, wherein:
the third electrode is characterized by an outer diameter, and
the outer diameter is greater than the second diameter.

8. The chuck of claim 1, wherein:
the first electrode is substantially semicircular, and
the second electrode is substantially semicircular.

9. The chuck of claim 1, further comprising:
one or more electrodes additional to the first electrode, the second electrode, and the third electrode, wherein:
an outer edge of the first electrode, an outer edge of the second electrode, and and an outer edge of the one or more electrodes may trace the circumference of a circle.

10. The chuck of claim 1, wherein:
the first electrode is configured such that when the substrate is disposed in the recessed portion and a first voltage is applied to the first electrode, a first electrostatic force holds the substrate to the chuck, and
the second electrode is configured such that when the substrate is disposed in the recessed portion and a second voltage is applied to the second electrode, a second electrostatic force holds the substrate to the chuck, the second voltage having an opposite polarity as the first voltage.

11. The chuck of claim 1, wherein further comprising a tuning circuit in electrical communication with the third electrode.

12. A plasma processing system, the system comprising:
an electrostatic chuck, the electrostatic chuck comprising:
a top surface, wherein:
the top surface defines a recessed portion of the chuck,
the recessed portion of the chuck is configured to support a substrate, and
the recessed portion of the chuck is characterized by a first diameter;
a first electrode and a second electrode, wherein:
the first electrode and the second electrode are disposed within the chuck,
the first electrode and the second electrode are substantially coplanar, and
the first electrode is separated from the second electrode; and
a third electrode, wherein:
the third electrode is disposed within the chuck,
the third electrode has an annular shape,
the third electrode is characterized by an inner diameter,
the inner diameter is greater than the first diameter,
the third electrode is separated from the first electrode and the second electrode, and
the third electrode is substantially parallel to the first electrode and the second electrode;
a first power source in electrical communication with the first electrode and the second electrode, wherein:
the first electrode and the second electrode are connected to the first power source such that the first electrode and the second electrode have opposite voltages when the first power source delivers voltage to the first electrode; and
a second power source in electrical communication with the third electrode.

13. The system of claim 12, wherein:
the first power source is a DC power source.

14. The system of claim 12, wherein:
the second power source is an RF power source.

15. A method of processing a substrate, the method comprising:
disposing the substrate on an electrostatic chuck, wherein:
the electrostatic chuck comprises a first electrode, a second electrode, and a third electrode,
the first electrode and the second electrode are substantially coplanar, and
the third electrode has an annular shape;
applying a first voltage to the first electrode;
applying a second voltage to the second electrode, wherein the second voltage is the opposite voltage of the first voltage; and
applying a third voltage to the third electrode.

16. The method of claim 15, further comprising:
forming a plasma in a processing region, the substrate disposed in the processing region.

17. The method of claim 15, wherein the third voltage is an RF voltage.

18. The method of claim 15, wherein the first voltage and the second voltage are DC voltages.

19. The method of claim 15, further comprising:
heating the electrostatic chuck to a temperature of at least 600° C.

20. The method of claim 15, wherein the first voltage has a magnitude less than or equal to 300 V.
